(19) United States
(12) Patent Application Publication
(10) Pub. No.: US 2025/0241058 A1
(43) Pub. Date: Jul. 24, 2025

(54) POWER DEVICES INCLUDING ENHANCEMENT-MODE SILICON TRANSISTORS AND DEPLETION-MODE GALLIUM NITRIDE TRANSISTORS AND PACKAGING THEREOF

(71) Applicant: ON-BRIGHT ELECTRONICS (SHANGHAI) CO., LTD., Shanghai (CN)

(72) Inventors: GUOHUA HUANG, Shanghai (CN); JIAN LIU, Shanghai (CN); YU CHEN, Shanghai (CN); ZHILIANG CHEN, Shanghai (CN)

(21) Appl. No.: 18/780,023

(22) Filed: Jul. 22, 2024

(30) Foreign Application Priority Data
Jan. 19, 2024 (CN) 202410081325.0

(51) Int. Cl. H01L 27/088; H01L 27/02; H01L 27/06; H01L 29/20; H01L 29/778

(52) U.S. Cl. CPC H10D 84/84; H10D 30/475; H10D 62/8503; H10D 84/811; H10D 89/60

(57) ABSTRACT

Power device and packaging thereof. For example, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; and a first transistor drain terminal electrically conductively connected to a second part of the silicon substrate through the first substrate surface.

### 1. CROSS-REFERENCES TO RELATED APPLICATIONS

This application claims priority to Chinese Patent Application No. 202410081325.0, filed Jan. 19, 2024, incorporated by reference herein for all purposes.

### 2. FIELD OF THE DISCLOSURE

Certain embodiments of the present disclosure are directed to devices. More particularly, some embodiments of the disclosure provide power devices including enhancement-mode silicon transistors and depletion-mode gallium nitride transistors and packaging thereof. Merely by way of example, some embodiments of the disclosure have been applied to low-voltage enhancement-mode silicon transistors. But it would be recognized that the disclosure has a much broader range of applicability.

### 3. BACKGROUND OF THE DISCLOSURE

Compared with conventional silicon (Si) based devices, conventional gallium nitride (GaN) based devices usually have excellent performance such as low on-resistance, fast switching speed and/or low switching loss due to large band gap, high breakdown electric field and/or fast charge carrier speed of gallium nitride (GaN).

A common type of gallium nitride (GaN) based device is GaN transistor. Conventional GaN transistors include enhancement-mode GaN transistors and depletion-mode GaN transistors. Conventional enhancement-mode GaN transistors often have a threshold voltage that is very close to the maximum gate-source voltage, so the conventional enhancement-mode GaN transistors usually have limited applications. In contrast, conventional depletion-mode GaN transistors often do not suffer from these limitations, and the transistors have a mature fabrication process. A depletion-mode GaN transistor often is used together with a low-voltage silicon transistor to form a power device with a common gate and common source structure. For example, the power device with the common gate and common source structure is in a shutdown state if the gate drive voltage for the low-voltage silicon transistor is at a low voltage level, and the power device is in an operation state if the gate drive voltage for the low-voltage silicon transistor is at a high voltage level. As an example, the power device with the common gate and common source structure is driven by a drive circuit that is designed for the low-voltage silicon transistor. The power device with the common gate and common source structure usually is compatible with the drive technology that has been widely used with low costs, so the power device is widely accepted for many applications.

FIG. 1 is a simplified diagram showing a conventional power device with a common gate and common source structure. The power device 100 includes a gate terminal 102, a source terminal 104, and a drain terminal 106. As shown in FIG. 1, the power device 100 includes a low-voltage enhancement-mode silicon transistor 110 and a depletion-mode gallium nitride transistor 160. The low-voltage enhancement-mode silicon transistor 110 includes a gate terminal 112, a source terminal 114, and a drain terminal 116. The depletion-mode gallium nitride transistor 160 includes a gate terminal 162, a source terminal 164, and a drain terminal 166. In some examples, the power device 100 is a power semiconductor device. For example, the low-voltage enhancement-mode silicon transistor 110 is the low-voltage enhancement-mode silicon transistor as shown in FIG. 2A and/or FIG. 2B. As an example, the depletion-mode gallium nitride transistor 160 is the depletion-mode gallium nitride transistor as shown in FIG. 3.

As shown in FIG. 1, the low-voltage enhancement-mode silicon transistor 110 and the depletion-mode gallium nitride transistor 160 are coupled to each other to form the common gate and common source structure for the power device 100. The gate terminal 162 of the depletion-mode gallium nitride transistor 160 is electrically conductively connected to the source terminal 114 of the low-voltage enhancement-mode silicon transistor 110, and the source terminal 164 of the depletion-mode gallium nitride transistor 160 is electrically conductively connected to the drain terminal 116 of the low-voltage enhancement-mode silicon transistor 110. The gate terminal 112 of the low-voltage enhancement-mode silicon transistor 110 is used as the gate terminal 102 of the power device 100, the source terminal 114 of the low-voltage enhancement-mode silicon transistor 110 is used as the source terminal 104 of the power device 100, and the drain terminal 166 of the depletion-mode gallium nitride transistor 160 is used as the drain terminal 106 of the power device 100.

As shown in FIG. 1, the voltage drop (e.g., V_{gs_Si}) from the gate terminal 112 to the source terminal 114 of the low-voltage enhancement-mode silicon transistor 110 is used to turn on and/or turn off the power device 100. If the voltage drop (e.g., V_{gs_Si}) from the gate terminal 112 to the source terminal 114 of the low-voltage enhancement-mode silicon transistor 110 is positive and larger than a threshold voltage of the low-voltage enhancement-mode silicon transistor 110, the low-voltage enhancement-mode silicon transistor 110 is turned on. For example, when the low-voltage enhancement-mode silicon transistor 110 is turned on, the voltage drop (e.g., V_{ds_Si}) from the drain terminal 116 to the source terminal 114 of the low-voltage enhancement-mode silicon transistor 110 is positive but close to zero and the voltage drop (e.g., V_{gs_GaN}) from the gate terminal 162 to the source terminal 164 of the depletion-mode gallium nitride transistor 160 is negative but close to zero, so the depletion-mode gallium nitride transistor 160 is also turned on and the power device 100 is in an operation state. As an example, when the low-voltage enhancement-mode silicon transistor 110 is turned off, the voltage drop (e.g., V_{ds_Si}) from the drain terminal 116 to the source terminal 114 of the low-voltage enhancement-mode silicon transistor 110 is positive and also significantly larger than zero and the voltage drop (e.g., V_{gs_GaN}) from the gate terminal 162 to the source terminal 164 of the depletion-mode gallium nitride transistor 160 is negative and also significantly smaller than zero, so the depletion-mode gallium nitride transistor 160 is also turned off and the power device 100 is in a shutdown state. Also the low-voltage enhancement-mode silicon transistor 110 includes a parasitic diode. The anode of the parasitic diode is electrically conductively connected to the source terminal 114 of the low-voltage enhancement-mode silicon transistor 110, and the cathode of the parasitic diode is electrically conductively connected to the drain terminal 116 of the low-voltage enhancement-mode silicon transistor 110.

FIG. 2A is a simplified diagram showing a conventional low-voltage enhancement-mode silicon transistor. The low-voltage enhancement-mode silicon transistor 290 includes a gate terminal 212, a source terminal 214, and a drain terminal 216. Additionally, the low-voltage enhancement-mode silicon transistor 290 includes a silicon substrate 200 that includes surfaces 210 and 220. In some examples, the gate terminal 212 of the low-voltage enhancement-mode silicon transistor 290 is attached indirectly to the surface 210 of the silicon substrate 200 through a dielectric layer (e.g., a silicon dioxide layer). For example, the dielectric layer (e.g., a silicon dioxide layer) is sandwiched between the gate terminal 212 of the low-voltage enhancement-mode silicon transistor 290 and the surface 210 of the silicon substrate 200. In certain examples, the source terminal 214 of the low-voltage enhancement-mode silicon transistor 290 is attached, directly or indirectly, to the surface 210 of the silicon substrate 200, and the drain terminal 216 of the low-voltage enhancement-mode silicon transistor 290 is attached, directly or indirectly, to the surface 220 of the silicon substrate 200. For example, the source terminal 214 of the low-voltage enhancement-mode silicon transistor 290 is electrically conductively connected to the surface 210 of the silicon substrate 200. As an example, the drain terminal 216 of the low-voltage enhancement-mode silicon transistor 290 is electrically conductively connected to the surface 220 of the silicon substrate 200.

In some examples, the low-voltage enhancement-mode silicon transistor 290 is used as the low-voltage enhancement-mode silicon transistor 110 of the power device 100. For example, the gate terminal 212 of the low-voltage enhancement-mode silicon transistor 290 is used as the gate terminal 112 of the low-voltage enhancement-mode silicon transistor 110. As an example, the source terminal 214 of the low-voltage enhancement-mode silicon transistor 290 is used as the source terminal 114 of the low-voltage enhancement-mode silicon transistor 110. For example, the drain terminal 216 of the low-voltage enhancement-mode silicon transistor 290 is used as the drain terminal 116 of the low-voltage enhancement-mode silicon transistor 110. In certain examples, the low-voltage enhancement-mode silicon transistor 290 includes a parasitic diode in the silicon substrate 200. For example, the anode of the parasitic diode is electrically conductively connected to the source terminal 214 of the low-voltage enhancement-mode silicon transistor 290. As an example, the cathode of the parasitic diode is electrically conductively connected to the drain terminal 216 of the low-voltage enhancement-mode silicon transistor 290.

FIG. 2B is a simplified diagram showing a conventional low-voltage enhancement-mode silicon transistor. The low-voltage enhancement-mode silicon transistor 1290 includes a source terminal 1214 and a drain terminal 1216. Additionally, the low-voltage enhancement-mode silicon transistor 1290 includes a gate 1222, a source 1224, a drain 1226, and a body region 1246. Moreover, the low-voltage enhancement-mode silicon transistor 1290 includes a dielectric layer 1228. Also, the low-voltage enhancement-mode silicon transistor 1290 includes contact plugs 1234.

As shown in FIG. 2B, the low voltage enhancement-mode silicon transistor 1290 includes a silicon substrate 1240, which includes surfaces 1242 and 1244. The silicon substrate 1240 includes the source 1224, the drain 1226 and the body region 1246. The silicon substrate 1240 does not include the gate 1222 and also does not include the dielectric layer 1228. Additionally, the gate 1222 (e.g., a polysilicon gate) is separated from the silicon substrate 1240 by the dielectric layer 1228 (e.g., a silicon dioxide layer). The dielectric layer 1228 (e.g., a silicon dioxide layer) is sandwiched between the gate 1222 (e.g., a polysilicon gate) and the silicon substrate 1240. Moreover, the source terminal 1214 is electrically conductively connected to the source 1224 through the contact plugs 1234 (e.g., tungsten plugs) and the surface 1242 of the silicon substrate 1240, and the drain terminal 1216 is electrically conductively connected to the drain 1226 through the surface 1244 of the silicon substrate 1240. Also, the source terminal 1214 is electrically conductively connected to the body region 1246 through the contact plugs 1234 (e.g., tungsten plugs) and the surface 1242 of the silicon substrate 1240, and the body region 1246 and the source 1224 are electrically conductively connected through the contact plugs 1234 (e.g., tungsten plugs) and the source terminal 1214. Additionally, the low-voltage enhancement-mode silicon transistor 1290 includes a gate terminal, which is electrically conductively connected to the gate 1222.

In certain examples, the low-voltage enhancement-mode silicon transistor 1290 includes a parasitic diode in the silicon substrate 1240. For example, the anode of the parasitic diode is electrically conductively connected to the source terminal 1214 of the low-voltage enhancement-mode silicon transistor 1290 (e.g., through the contact plugs 1234). As an example, the cathode of the parasitic diode is electrically conductively connected to the drain terminal 1216 of the low-voltage enhancement-mode silicon transistor 1290 (e.g., through the surface 1244 of the silicon substrate 1240). In some examples, the low-voltage enhancement-mode silicon transistor 1290 is the same as the low-voltage enhancement-mode silicon transistor 290 as shown in FIG. 2A. For example, the gate terminal (e.g., the gate terminal 212) of the low-voltage enhancement-mode silicon transistor 1290 is electrically conductively connected to the gate 1222.

In certain examples, the low-voltage enhancement-mode silicon transistor 1290 is used as the low-voltage enhancement-mode silicon transistor 110 of the power device 100. For example, the gate terminal of the low-voltage enhancement-mode silicon transistor 1290 is used as the gate terminal 112 of the low-voltage enhancement-mode silicon transistor 110. As an example, the source terminal 1214 of the low-voltage enhancement-mode silicon transistor 1290 is used as the source terminal 114 of the low-voltage enhancement-mode silicon transistor 110. For example, the drain terminal 1216 of the low-voltage enhancement-mode silicon transistor 1290 is used as the drain terminal 116 of the low-voltage enhancement-mode silicon transistor 110.

FIG. 3 is a simplified diagram showing a conventional depletion-mode gallium nitride transistor. The depletion-mode gallium nitride transistor 360 includes a gate terminal 362, a source terminal 364, and a drain terminal 366. Additionally, the depletion-mode gallium nitride transistor 360 includes a barrier layer 328 and a transistor structure 300. The transistor structure 300 includes surfaces 310 and 320. In some examples, the transistor structure 300 includes a gallium nitride layer 370, a buffer layer 380, and a silicon substrate 390. For example, the gallium nitride layer 370 is located, directly or indirectly, on the buffer layer 380, and the buffer layer 380 is located, directly or indirectly, on the silicon substrate 390. As an example, the buffer layer 380 is sandwiched between the gallium nitride layer 370 and the silicon substrate 390. One surface of the gallium nitride layer 370 is the surface 310 of the transistor structure 300, and one surface of the silicon substrate 390 is the surface 320 of the transistor structure 300. In certain examples, the gate terminal 362 of the depletion-mode gallium nitride transistor 360 is attached indirectly to the surface 310 of the transistor structure 300 through the barrier layer 328. For example, the gate terminal 362 of the depletion-mode gallium nitride transistor 360 is also used as a gate of the depletion-mode gallium nitride transistor 360. As an example, the barrier layer 328 is sandwiched between the gate terminal 362 of the depletion-mode gallium nitride transistor 360 and the surface 310 of the transistor structure 300.

As shown in FIG. 3, the source terminal 364 of the depletion-mode gallium nitride transistor 360 is attached, directly or indirectly, to the surface 310 of the transistor structure 300, and the drain terminal 366 of the depletion-mode gallium nitride transistor 360 is attached, directly or indirectly, to the surface 310 of the transistor structure 300. For example, the source terminal 364 of the depletion-mode gallium nitride transistor 360 is electrically conductively connected to a part of the gallium nitride layer 370 through the surface 310. As an example, the drain terminal 366 of the depletion-mode gallium nitride transistor 360 is electrically conductively connected to a part of the gallium nitride layer 370 through the surface 310.

In some examples, the barrier layer 328 is made of aluminum gallium nitride, and the buffer layer 380 includes an aluminum nitride layer and/or one or more aluminum gallium nitride layers. In certain examples, the depletion-mode gallium nitride transistor 360 is used as the depletion-mode gallium nitride transistor 160 of the power device 100. For example, the gate terminal 362 of the depletion-mode gallium nitride transistor 360 is used as the gate terminal 162 of the depletion-mode gallium nitride transistor 160. As an example, the source terminal 364 of the depletion-mode gallium nitride transistor 360 is used as the source terminal 164 of the depletion-mode gallium nitride transistor 160. For example, the drain terminal 366 of the depletion-mode gallium nitride transistor 360 is used as the drain terminal 166 of the depletion-mode gallium nitride transistor 160.

FIG. 4 is a simplified diagram showing certain components of a conventional chip package for the power device 100 as shown in FIG. 1. The chip package 400 includes a lead frame 402 and electrically conductive plates 404, 406 and 408. Additionally, the chip package 400 also includes an electrically insulative plate 412 and an electrically conductive plate 414. The electrically conductive plate 404 is attached to the electrically insulative plate 412, and the electrically insulative plate 412 is attached to the electrically conductive plate 414. The electrically insulative plate 412 is sandwiched between the electrically conductive plate 404 and the electrically conductive plate 414.

As shown in FIG. 4, the depletion-mode gallium nitride transistor 160 is placed on the electrically conductive plate 404 by attaching the surface 320 of the depletion-mode gallium nitride transistor 160 to the electrically conductive plate 404. For example, the surface 320 of the depletion-mode gallium nitride transistor 160 is attached to the electrically conductive plate 404 through electrically conductive paste (e.g., silver conductive paste). As an example, the surface 320 of the depletion-mode gallium nitride transistor 160 is electrically conductively connected to the electrically conductive plate 404. In contrast, the low-voltage enhancement-mode silicon transistor 110 is placed on the electrically conductive plate 414 by attaching the drain terminal 116 of the low-voltage enhancement-mode silicon transistor 110 to the electrically conductive plate 414, which is located on the electrically insulative plate 412 that is located on the electrically conductive plate 404. For example, the drain terminal 116 of the low-voltage enhancement-mode silicon transistor 110 is attached to the electrically conductive plate 414 with solder. As an example, the drain terminal 116 of the low-voltage enhancement-mode silicon transistor 110 is electrically conductively connected to the electrically conductive plate 414.

The low-voltage enhancement-mode silicon transistor 110 includes the gate terminal 112, the source terminal 114, and the drain terminal 116, and the depletion-mode gallium nitride transistor 160 includes the gate terminal 162, the source terminal 164, and the drain terminal 166. The gate terminal 112 of the low-voltage enhancement-mode silicon transistor 110 is electrically conductively connected to the electrically conductive plate 406 by one or more electrically conductive wires 462, and the source terminal 114 of the low-voltage enhancement-mode silicon transistor 110 is electrically conductively connected to the electrically conductive plate 404 by one or more electrically conductive wires 464. Additionally, the drain terminal 116 of the low-voltage enhancement-mode silicon transistor 110 is electrically conductively connected to the electrically conductive plate 414.

The source terminal 164 of the depletion-mode gallium nitride transistor 160 is electrically conductively connected to the electrically conductive plate 414 by one or more electrically conductively wires 466. Additionally, the gate terminal 162 of the depletion-mode gallium nitride transistor 160 is electrically conductively connected to the electrically conductive plate 404 by one or more electrically conductive wires 472, and the drain terminal 166 of the depletion-mode gallium nitride transistor 160 is electrically conductively connected to the electrically conductive plate 408 by one or more electrically conductive wires 476.

As shown in FIG. 4, the drain terminal 116 of the low-voltage enhancement-mode silicon transistor 110 and the source terminal 164 of the depletion-mode gallium nitride transistor 160 are electrically conductively connected through the electrically conductive plate 414. The electrically conductive plate 406 is used as the gate terminal 102 of the power device 100, and the electrically conductive plate 408 is used as the drain terminal 106 of the power device 100. Additionally, the source terminal 114 of the low-voltage enhancement-mode silicon transistor 110 and the gate terminal 162 of the depletion-mode gallium nitride transistor 160 are electrically conductively connected through the electrically conductive plate 404, which is used as the source terminal 104 of the power device 100.

FIG. 5 is a simplified diagram showing a conventional low-voltage enhancement-mode silicon transistor. The low-voltage enhancement-mode silicon transistor 510 includes a gate terminal 512, a source terminal 514, and a drain terminal 516. Additionally, the low-voltage enhancement-mode silicon transistor 510 includes a gate 522, a source 524, a drain 526, and a body region 546. Moreover, the low-voltage enhancement-mode silicon transistor 510 includes a dielectric layer 528 and a shallow trench isolation (STI) 530. Also, the low-voltage enhancement-mode silicon transistor 510 includes contact plugs 532, 534 and 536.

As shown in FIG. 5, the low voltage enhancement-mode silicon transistor 510 includes a silicon substrate 540, which includes surfaces 542 and 544. The silicon substrate 540 includes the source 524, the drain 526 and the body region 546. The silicon substrate 540 does not include the shallow trench isolation (STI) 530, which is filled with one or more dielectric materials (e.g., silicon dioxide). Additionally, the gate terminal 512 is electrically conductively connected to the gate 522 through the contact plug 532 (e.g., a tungsten plug). The gate 522 (e.g., a polysilicon layer) is located on the dielectric layer 528 (e.g., a silicon dioxide layer), and the dielectric layer 528 is located on the surface 542 of the silicon substrate 540 and the shallow trench isolation (STI) 530. A part of the dielectric layer 528 (e.g., a silicon dioxide layer) is sandwiched between the gate 522 (e.g., a polysilicon layer) and the surface 542 of the silicon substrate 540, and another part of the dielectric layer 528 (e.g., a silicon dioxide layer) is sandwiched between the gate 522 (e.g., a polysilicon layer) and the shallow trench isolation (STI) 530. Moreover, the source terminal 514 is electrically conductively connected to the source 524 through the contact plug 534 (e.g., a tungsten plug) and the surface 542 of the silicon substrate 540, and the drain terminal 516 is electrically conductively connected to the drain 526 through the contact plug 536 (e.g., a tungsten plug) and the surface 542 of the silicon substrate 540. Also, the source terminal 514 is electrically conductively connected to the body region 546 through the contact plug 534 (e.g., a tungsten plug) and the surface 542 of the silicon substrate 540, and the body region 546 and the source 524 are electrically conductively connected through the contact plug 534 (e.g., a tungsten plug). In certain examples, the low-voltage enhancement-mode silicon transistor 510 includes a parasitic diode in the silicon substrate 540. For example, the anode of the parasitic diode is electrically conductively connected to the source terminal 514 of the low-voltage enhancement-mode silicon transistor 510 (e.g., through the contact plug 534). As an example, the cathode of the parasitic diode is electrically conductively connected to the drain terminal 516 of the low-voltage enhancement-mode silicon transistor 510 (e.g., through the contact plug 536).

Hence it is highly desirable to improve the technique for power devices.

### 4. BRIEF SUMMARY OF THE DISCLOSURE

Certain embodiments of the present disclosure are directed to devices. More particularly, some embodiments of the disclosure provide power devices including enhancement-mode silicon transistors and depletion-mode gallium nitride transistors and packaging thereof. Merely by way of example, some embodiments of the disclosure have been applied to low-voltage enhancement-mode silicon transistors. But it would be recognized that the disclosure has a much broader range of applicability.

According to certain embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; and a first transistor drain terminal electrically conductively connected to a second part of the silicon substrate through the first substrate surface; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor; wherein: the second substrate surface of the silicon substrate and the second structure surface of the transistor structure are electrically conductively connected.

According to some embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; and an electrostatic discharge protection component electrically conductively connected to the first transistor source terminal and electrically conductively connected to the first transistor gate terminal; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor.

According to certain embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; and a resistor component electrically conductively connected to the first transistor source terminal and electrically conductively connected to a resistor contact; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor.

According to some embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; and a voltage clamper component electrically conductively connected to the first transistor source terminal and electrically conductively connected to the first transistor drain terminal; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor.

According to certain embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; an electrostatic discharge protection component electrically conductively connected to the first transistor source terminal and electrically conductively connected to the first transistor gate terminal; a resistor component electrically conductively connected to the first transistor source terminal and electrically conductively connected to a resistor contact; and a voltage clamper component electrically conductively connected to the first transistor source terminal and electrically conductively connected to the first transistor drain terminal; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor.

According to some embodiments, a chip package for a power device, the chip package comprising: a first electrically conductive plate; a second electrically conductive plate; a third electrically conductive plate; and a power device including an enhancement-mode silicon transistor and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; and a first transistor drain terminal electrically conductively connected to a second part of the silicon substrate through the first substrate surface; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the second substrate surface of the silicon substrate is electrically conductively attached to the first electrically conductive plate; and the second structure surface of the transistor structure is electrically conductively attached to the first electrically conductive plate; wherein: the first transistor gate terminal of the enhancement-mode silicon transistor is electrically conductively connected to the second electrically conductive plate; the first transistor source terminal of the enhancement-mode silicon transistor is electrically conductively connected to the first electrically conductive plate; and the first transistor drain terminal of the enhancement-mode silicon transistor is electrically conductively connected to the second transistor source terminal of the depletion-mode gallium nitride transistor; wherein: the second transistor gate terminal of the depletion-mode gallium nitride transistor is electrically conductively connected to the first electrically conductive plate; and the second transistor drain terminal of the depletion-mode gallium nitride transistor is electrically conductively connected to the third electrically conductive plate.

Depending upon embodiment, one or more benefits may be achieved. These benefits and various additional objects, features and advantages of the present disclosure can be fully appreciated with reference to the detailed description and accompanying drawings that follow.

### 5. BRIEF DESCRIPTION OF THE DRAWINGS

FIG. 1 is a simplified diagram showing a conventional power device with a common gate and common source structure.

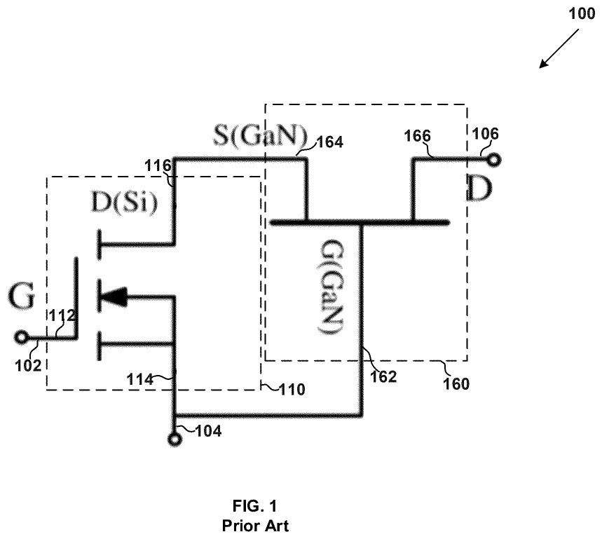

FIG. 2A is a simplified diagram showing a conventional low-voltage enhancement-mode silicon transistor.

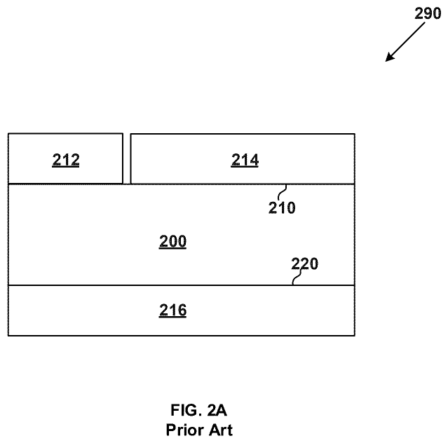

FIG. 2B is a simplified diagram showing a conventional low-voltage enhancement-mode silicon transistor.

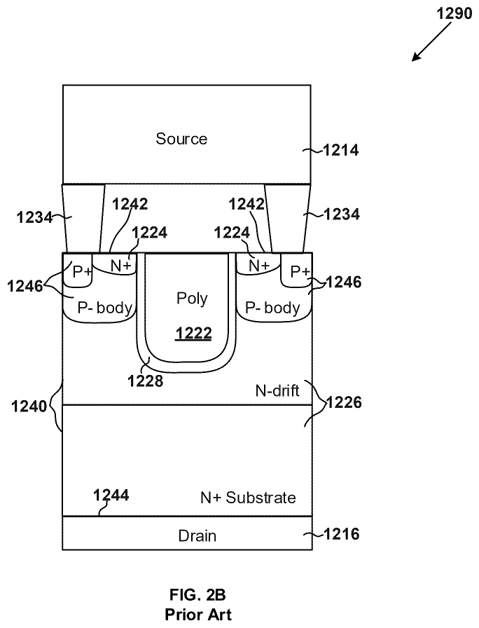

FIG. 3 is a simplified diagram showing a conventional depletion-mode gallium nitride transistor.

FIG. 4 is a simplified diagram showing certain components of a conventional chip package for the power device as shown in FIG. 1.

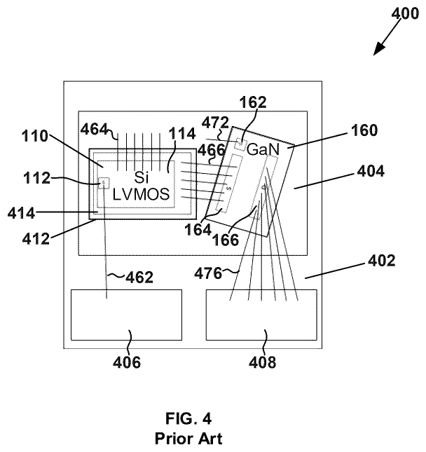

FIG. 5 is a simplified diagram showing a conventional low-voltage enhancement-mode silicon transistor.

FIG. 6 is a simplified diagram showing a power device with a common gate and common source structure according to certain embodiments of the present disclosure.

FIG. 7 is a simplified diagram showing an enhancement-mode silicon transistor as part of the power device as shown in FIG. 6 according to some embodiments of the present disclosure.

FIG. 8 is a simplified diagram showing an enhancement-mode silicon transistor as part of the power device as shown in FIG. 6 according to certain embodiments of the present disclosure.

FIG. 9 is a simplified diagram showing an enhancement-mode silicon transistor as part of the power device as shown in FIG. 6 according to some embodiments of the present disclosure.

FIG. 10 is a simplified diagram showing an enhancement-mode silicon transistor as part of the power device as shown in FIG. 6 according to certain embodiments of the present disclosure.

FIG. 11 is a simplified diagram showing certain components of a chip package for the power device as shown in FIG. 6 according to some embodiments of the present disclosure.

### 6. DETAILED DESCRIPTION OF THE DISCLOSURE

Certain embodiments of the present disclosure are directed to devices. More particularly, some embodiments of the disclosure provide power devices including enhancement-mode silicon transistors and depletion-mode gallium nitride transistors and packaging thereof. Merely by way of example, some embodiments of the disclosure have been applied to low-voltage enhancement-mode silicon transistors. But it would be recognized that the disclosure has a much broader range of applicability.

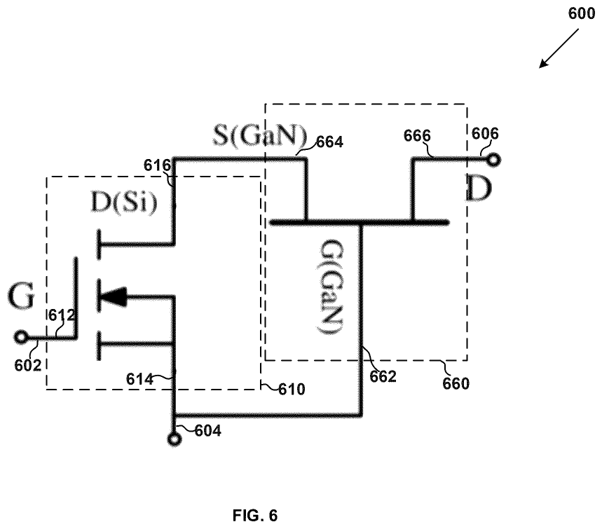

FIG. 6 is a simplified diagram showing a power device with a common gate and common source structure according to certain embodiments of the present disclosure. This diagram is merely an example, which should not unduly limit the scope of the claims. One of ordinary skill in the art would recognize many variations, alternatives, and modifications. The power device 600 includes a gate terminal 602, a source terminal 604, and a drain terminal 606. Also, the power device 600 includes an enhancement-mode silicon transistor 610 and a depletion-mode gallium nitride transistor 660. In some examples, the power device 600 is a power semiconductor device. For examples, the enhancement-mode silicon transistor 610 includes a gate terminal 612, a source terminal 614, and a drain terminal 616. As an example, the depletion-mode gallium nitride transistor 660 includes a gate terminal 662, a source terminal 664, and a drain terminal 666. Although the above has been shown using a selected group of components for the power device, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

As shown in FIG. 6, the enhancement-mode silicon transistor 610 and the depletion-mode gallium nitride transistor 660 are coupled to each other to form the common gate and common source structure for the power device 600 according to some embodiments. For example, the gate terminal 662 of the depletion-mode gallium nitride transistor 660 is electrically conductively connected to the source terminal 614 of the enhancement-mode silicon transistor 610, and the source terminal 664 of the depletion-mode gallium nitride transistor 660 is electrically conductively connected to the drain terminal 616 of the enhancement-mode silicon transistor 610. As an example, the gate terminal 612 of the enhancement-mode silicon transistor 610 is used as the gate terminal 602 of the power device 600, the source terminal 614 of the enhancement-mode silicon transistor 610 is used as the source terminal 604 of the power device 600, and the drain terminal 666 of the depletion-mode gallium nitride transistor 660 is used as the drain terminal 606 of the power device 600.

In certain embodiments, the voltage drop (e.g., V_{gs_Si}) from the gate terminal 612 to the source terminal 614 of the enhancement-mode silicon transistor 610 is used to turn on and/or turn off the power device 600. In some examples, if the voltage drop (e.g., V_{gs_Si}) from the gate terminal 612 to the source terminal 614 of the enhancement-mode silicon transistor 610 is positive and larger than a threshold voltage of the enhancement-mode silicon transistor 610, the enhancement-mode silicon transistor 610 is turned on. For example, when the enhancement-mode silicon transistor 610 is turned on, the voltage drop (e.g., V_{ds_Si}) from the drain terminal 616 to the source terminal 614 of the enhancement-mode silicon transistor 610 is positive but close to zero and the voltage drop (e.g., V_{gs_GaN}) from the gate terminal 662 to the source terminal 664 of the depletion-mode gallium nitride transistor 660 is negative but close to zero, so the depletion-mode gallium nitride transistor 660 is also turned on and the power device 600 is in an operation state. As an example, when the enhancement-mode silicon transistor 610 is turned off, the voltage drop (e.g., V_{ds_Si}) from the drain terminal 616 to the source terminal 614 of the enhancement-mode silicon transistor 610 is positive and also significantly larger than zero and the voltage drop (e.g., V_{gs_GaN}) from the gate terminal 662 to the source terminal 664 of the depletion-mode gallium nitride transistor 660 is negative and also significantly smaller than zero, so the depletion-mode gallium nitride transistor 660 is also turned off and the power device 600 is in a shutdown state.

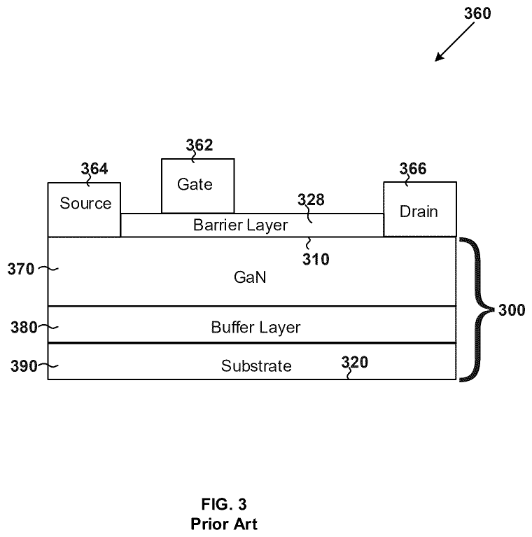

According to some embodiments, the depletion-mode gallium nitride transistor 660 is the depletion-mode gallium nitride transistor 360 as shown in FIG. 3. For example, the gate terminal 362 of the depletion-mode gallium nitride transistor 360 is used as the gate terminal 662 of the depletion-mode gallium nitride transistor 660. As an example, the source terminal 364 of the depletion-mode gallium nitride transistor 360 is used as the source terminal 664 of the depletion-mode gallium nitride transistor 660. For example, the drain terminal 366 of the depletion-mode gallium nitride transistor 360 is used as the drain terminal 666 of the depletion-mode gallium nitride transistor 660.

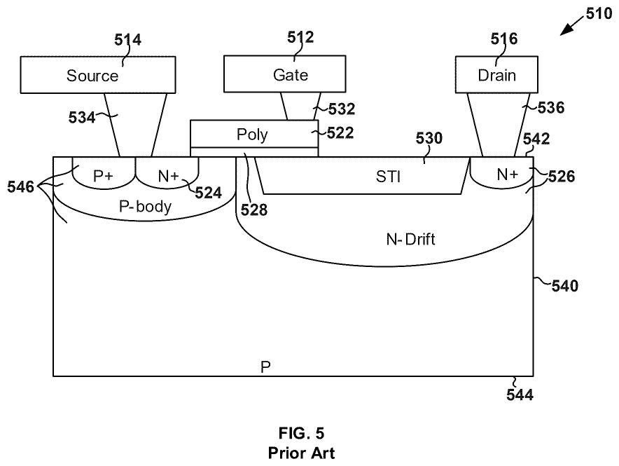

In certain embodiments, the enhancement-mode silicon transistor 610 is the low-voltage enhancement-mode silicon transistor 510 as shown in FIG. 5. For example, the gate terminal 512 of the low-voltage enhancement-mode silicon transistor 510 is used as the gate terminal 612 of the enhancement-mode silicon transistor 610. As an example, the source terminal 514 of the low-voltage enhancement-mode silicon transistor 510 is used as the source terminal 614 of the enhancement-mode silicon transistor 610. For example, the drain terminal 516 of the low-voltage enhancement-mode silicon transistor 510 is used as the drain terminal 616 of the enhancement-mode silicon transistor 610.

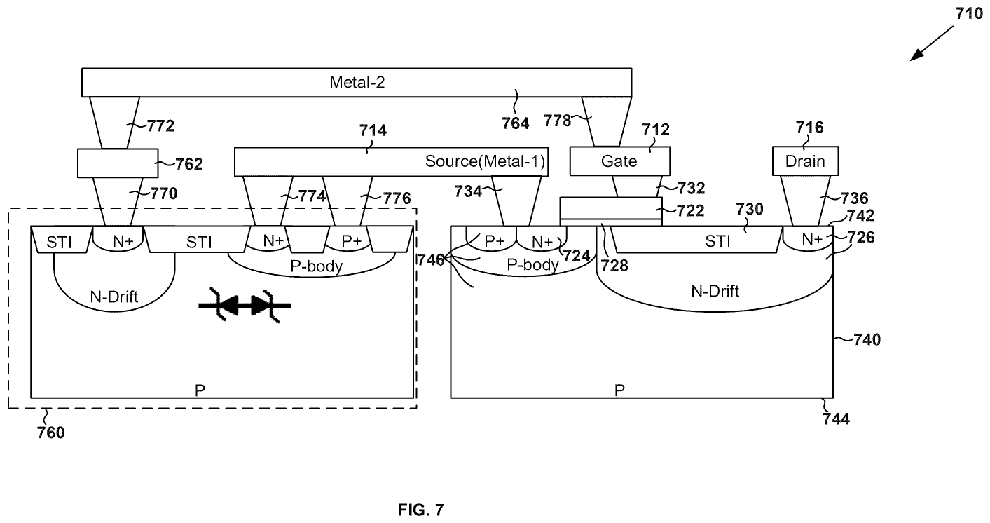

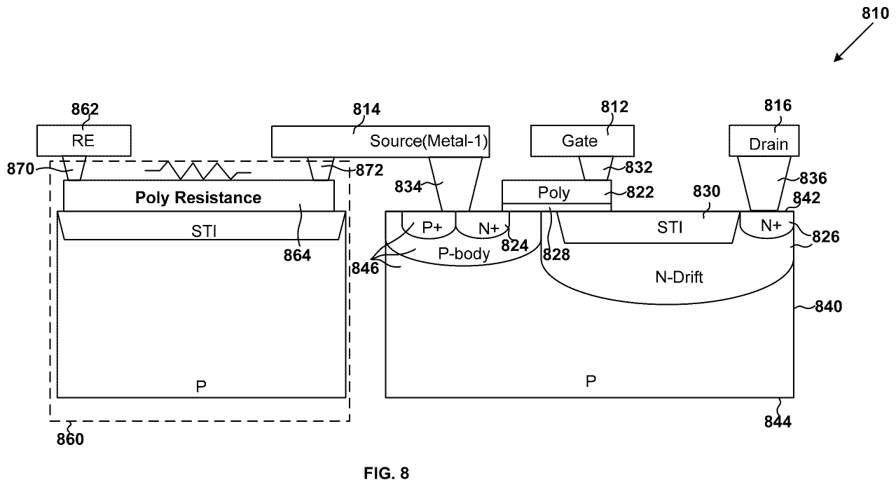

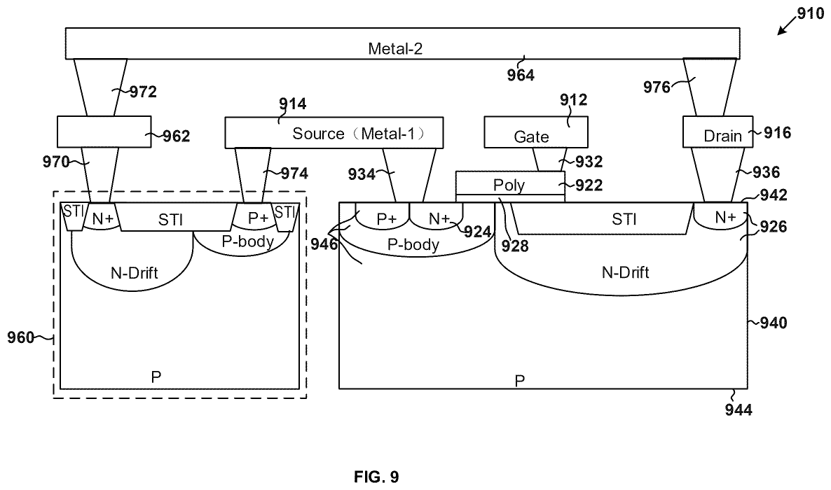

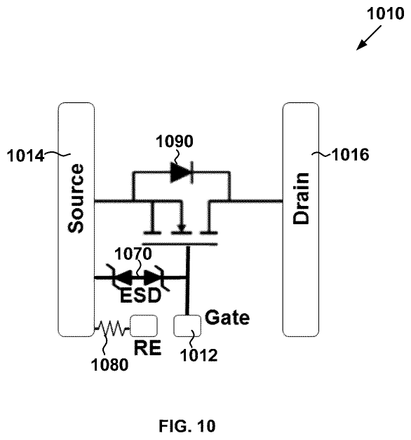

In some embodiments, the enhancement-mode silicon transistor 610 is the enhancement-mode silicon transistor as shown in FIG. 7. In certain embodiments, the enhancement-mode silicon transistor 610 is the enhancement-mode silicon transistor as shown in FIG. 8. In some embodiments, the enhancement-mode silicon transistor 610 is the enhancement-mode silicon transistor as shown in FIG. 9. In some embodiments, the enhancement-mode silicon transistor 610 is the enhancement-mode silicon transistor as shown in FIG. 10.

FIG. 7 is a simplified diagram showing an enhancement-mode silicon transistor as part of the power device 600 as shown in FIG. 6 according to some embodiments of the present disclosure. This diagram is merely an example, which should not unduly limit the scope of the claims. One of ordinary skill in the art would recognize many variations, alternatives, and modifications. The enhancement-mode silicon transistor 710 includes a gate terminal 712, a source terminal 714, and a drain terminal 716. Additionally, the enhancement-mode silicon transistor 710 includes a gate 722, a source 724, a drain 726, and a body region 746. Moreover, the enhancement-mode silicon transistor 710 includes a dielectric layer 728 and a shallow trench isolation (STI) 730. Also, the enhancement-mode silicon transistor 710 includes contact plugs 732, 734 and 736. Additionally, the enhancement-mode silicon transistor 710 includes an electrostatic discharge protection (ESD) component 760, a contact 762, an interconnect 764, and contact plugs 770, 772, 774, 776 and 778. For example, the enhancement-mode silicon transistor 710 has a threshold voltage that ranges from 3 volts to 5 volts. As an example, the enhancement-mode silicon transistor 710 is a low-voltage enhancement-mode silicon transistor. Although the above has been shown using a selected group of components for the enhancement-mode silicon transistor, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, as shown in FIG. 7, the enhancement-mode silicon transistor 710 includes a silicon substrate 740, which includes surfaces 742 and 744. In some examples, the silicon substrate 740 includes the source 724, the drain 726, the shallow trench isolation (STI) 730, and the body region 746. In certain examples, the gate terminal 712 is electrically conductively connected to the gate 722 through the contact plug 732 (e.g., a tungsten plug). For example, the gate 722 (e.g., a polysilicon layer) is located on the dielectric layer 728 (e.g., a silicon dioxide layer), and the dielectric layer 728 is located on the surface 742 of the silicon substrate 740. As an example, the dielectric layer 728 (e.g., a silicon dioxide layer) is sandwiched between the gate 722 (e.g., a polysilicon layer) and the surface 742 of the silicon substrate 740. In some examples, the source terminal 714 is electrically conductively connected to the source 724 through the contact plug 734 (e.g., a tungsten plug) and the surface 742 of the silicon substrate 740, and the drain terminal 716 is electrically conductively connected to the drain 726 through the contact plug 736 (e.g., a tungsten plug) and the surface 742 of the silicon substrate 740. In certain examples, the source terminal 714 is electrically conductively connected to the body region 746 through the contact plug 734 (e.g., a tungsten plug) and the surface 742 of the silicon substrate 740, and the body region 746 and the source 724 are electrically conductively connected through the contact plug 734 (e.g., a tungsten plug). In some examples, the enhancement-mode silicon transistor 710 includes a parasitic diode in the silicon substrate 740. For example, the anode of the parasitic diode is electrically conductively connected to the source terminal 714 of the enhancement-mode silicon transistor 710 (e.g., through the contact plug 734). As an example, the cathode of the parasitic diode is electrically conductively connected to the drain terminal 716 of the enhancement-mode silicon transistor 710 (e.g., through the contact plug 736).

According to some embodiments, the source terminal 714 is used as an interconnect (e.g., a copper interconnect), which is also electrically conductively connected to the electrostatic discharge protection (ESD) component 760 through the contact plug 774 (e.g., a tungsten plug) and the contact plug 776 (e.g., a tungsten plug). In certain examples, the electrostatic discharge protection (ESD) component 760 is electrically conductively connected to the gate terminal 712. For example, the electrostatic discharge protection (ESD) component 760 is electrically conductively connected to the contact 762 through the contact plug 770 (e.g., a tungsten plug). As an example, the contact 762 is electrically conductively connected to the interconnect 764 (e.g., a copper interconnect) through the contact plug 772 (e.g., a tungsten plug), and the interconnect 764 (e.g., a copper interconnect) is electrically conductively connected to the gate terminal 712 through the contact plug 778 (e.g., a tungsten plug).

In certain embodiments, according to the Human Body Model (HBM) for electrostatic discharge (ESD), the electrostatic discharge protection (ESD) component 760 can help prevent damage to the enhancement-mode silicon transistor 710 if the voltage drop (e.g., V_{gs_Si}) from the gate terminal 712 to the source terminal 714 of the enhancement-mode silicon transistor 710 is smaller than or equal to 4 KV.

In some embodiments, the enhancement-mode silicon transistor 710 is used as the enhancement-mode silicon transistor 610 of the power device 600. For example, the gate terminal 712 of the enhancement-mode silicon transistor 710 is used as the gate terminal 612 of the enhancement-mode silicon transistor 610. As an example, the source terminal 714 of the enhancement-mode silicon transistor 710 is used as the source terminal 614 of the enhancement-mode silicon transistor 610. For example, the drain terminal 716 of the enhancement-mode silicon transistor 710 is used as the drain terminal 616 of the enhancement-mode silicon transistor 610.

FIG. 8 is a simplified diagram showing an enhancement-mode silicon transistor as part of the power device 600 as shown in FIG. 6 according to certain embodiments of the present disclosure. This diagram is merely an example, which should not unduly limit the scope of the claims. One of ordinary skill in the art would recognize many variations, alternatives, and modifications. The enhancement-mode silicon transistor 810 includes a gate terminal 812, a source terminal 814, and a drain terminal 816. Additionally, the enhancement-mode silicon transistor 810 includes a gate 822, a source 824, a drain 826, and a body region 846. Moreover, the enhancement-mode silicon transistor 810 includes a dielectric layer 828 and a shallow trench isolation (STI) 830. Also, the enhancement-mode silicon transistor 810 includes contact plugs 832, 834 and 836. Additionally, the enhancement-mode silicon transistor 810 includes a resistor component 860, a resistor contact 862, and contact plugs 870 and 872. For example, the enhancement-mode silicon transistor 810 has a threshold voltage that ranges from 3 volts to 5 volts. As an example, the enhancement-mode silicon transistor 810 is a low-voltage enhancement-mode silicon transistor. Although the above has been shown using a selected group of components for the enhancement-mode silicon transistor, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to some embodiments, as shown in FIG. 8, the enhancement-mode silicon transistor 810 includes a silicon substrate 840, which includes surfaces 842 and 844. In certain examples, the silicon substrate 840 includes the source 824, the drain 826, the shallow trench isolation (STI) 830, and the body region 846. In some examples, the gate terminal 812 is electrically conductively connected to the gate 822 through the contact plug 832 (e.g., a tungsten plug). For example, the gate 822 (e.g., a polysilicon layer) is located on the dielectric layer 828 (e.g., a silicon dioxide layer), and the dielectric layer 828 is located on the surface 842 of the silicon substrate 840. As an example, the dielectric layer 828 (e.g., a silicon dioxide layer) is sandwiched between the gate 822 (e.g., a polysilicon layer) and the surface 842 of the silicon substrate 840. In certain examples, the source terminal 814 is electrically conductively connected to the source 824 through the contact plug 834 (e.g., a tungsten plug) and the surface 842 of the silicon substrate 840, and the drain terminal 816 is electrically conductively connected to the drain 826 through the contact plug 836 (e.g., a tungsten plug) and the surface 842 of the silicon substrate 840. In some examples, the source terminal 814 is electrically conductively connected to the body region 846 through the contact plug 834 (e.g., a tungsten plug) and the surface 842 of the silicon substrate 840, and the body region 846 and the source 824 are electrically conductively connected through the contact plug 834 (e.g., a tungsten plug). In certain examples, the enhancement-mode silicon transistor 810 includes a parasitic diode in the silicon substrate 840. For example, the anode of the parasitic diode is electrically conductively connected to the source terminal 814 of the enhancement-mode silicon transistor 810 (e.g., through the contact plug 834). As an example, the cathode of the parasitic diode is electrically conductively connected to the drain terminal 816 of the enhancement-mode silicon transistor 810 (e.g., through the contact plug 836).

According to certain embodiments, the source terminal 814 is used as an interconnect (e.g., a copper interconnect), which is also electrically conductively connected to the resistor component 860 through the contact plug 872 (e.g., a tungsten plug). In some examples, the resistor component 860 is also electrically conductively connected to the resistor contact 862 through the contact plug 870 (e.g., a tungsten plug). In certain examples, the resistor contact 862 is electrically conductively connected to the gate terminal 812 through an interconnect (e.g., a copper interconnect).

In some embodiments, the resistor component 860 includes a polysilicon resistor 864. For example, the resistance value of the polysilicon resistor 864 between the contact plugs 870 and 872 ranges from 10 KΩ to 1 MΩ. As an example, the resistance value of the polysilicon resistor 864 between the contact plugs 870 and 872 ranges from 500 KΩ to 1 MΩ. In certain examples, the resistor component 860 can help prevent the power device 600 from being mistakenly turned on if the power device 600 includes the enhancement-mode silicon transistor 810 as the enhancement-mode silicon transistor 610.

In certain embodiments, the enhancement-mode silicon transistor 810 is used as the enhancement-mode silicon transistor 610 of the power device 600. For example, the gate terminal 812 of the enhancement-mode silicon transistor 810 is used as the gate terminal 612 of the enhancement-mode silicon transistor 610. As an example, the source terminal 814 of the enhancement-mode silicon transistor 810 is used as the source terminal 614 of the enhancement-mode silicon transistor 610. For example, the drain terminal 816 of the enhancement-mode silicon transistor 810 is used as the drain terminal 616 of the enhancement-mode silicon transistor 610.

FIG. 9 is a simplified diagram showing an enhancement-mode silicon transistor as part of the power device 600 as shown in FIG. 6 according to some embodiments of the present disclosure. This diagram is merely an example, which should not unduly limit the scope of the claims. One of ordinary skill in the art would recognize many variations, alternatives, and modifications. The enhancement-mode silicon transistor 910 includes a gate terminal 912, a source terminal 914, and a drain terminal 916. Additionally, the enhancement-mode silicon transistor 910 includes a gate 922, a source 924, a drain 926, and a body region 946. Moreover, the enhancement-mode silicon transistor 910 includes a dielectric layer 928 and a shallow trench isolation (STI) 930. Also, the enhancement-mode silicon transistor 910 includes contact plugs 932, 934 and 936. Additionally, the enhancement-mode silicon transistor 910 includes a voltage clamper component 960, a contact 962, an interconnect 964, and contact plugs 970, 972, 974 and 976. For example, the enhancement-mode silicon transistor 910 has a threshold voltage that ranges from 3 volts to 5 volts. As an example, the enhancement-mode silicon transistor 910 is a low-voltage enhancement-mode silicon transistor. Although the above has been shown using a selected group of components for the enhancement-mode silicon transistor, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, as shown in FIG. 9, the enhancement-mode silicon transistor 910 includes a silicon substrate 940, which includes surfaces 942 and 944. In some examples, the silicon substrate 940 includes the source 924, the drain 926, the shallow trench isolation (STI) 930, and the body region 946. In certain examples, the gate terminal 912 is electrically conductively connected to the gate 922 through the contact plug 932 (e.g., a tungsten plug). For example, the gate 922 (e.g., a polysilicon layer) is located on the dielectric layer 928 (e.g., a silicon dioxide layer), and the dielectric layer 928 is located on the surface 942 of the silicon substrate 940. As an example, the dielectric layer 928 (e.g., a silicon dioxide layer) is sandwiched between the gate 922 (e.g., a polysilicon layer) and the surface 942 of the silicon substrate 940. In some examples, the source terminal 914 is electrically conductively connected to the source 924 through the contact plug 934 (e.g., a tungsten plug) and the surface 942 of the silicon substrate 940, and the drain terminal 916 is electrically conductively connected to the drain 926 through the contact plug 936 (e.g., a tungsten plug) and the surface 942 of the silicon substrate 940. In certain examples, the source terminal 914 is electrically conductively connected to the body region 946 through the contact plug 934 (e.g., a tungsten plug) and the surface 942 of the silicon substrate 940, and the body region 946 and the source 924 are electrically conductively connected through the contact plug 934 (e.g., a tungsten plug). In some examples, the enhancement-mode silicon transistor 910 includes a parasitic diode in the silicon substrate 940. For example, the anode of the parasitic diode is electrically conductively connected to the source terminal 914 of the enhancement-mode silicon transistor 910 (e.g., through the contact plug 934). As an example, the cathode of the parasitic diode is electrically conductively connected to the drain terminal 916 of the enhancement-mode silicon transistor 910 (e.g., through the contact plug 936).

According to some embodiments, the source terminal 914 is used as an interconnect (e.g., a copper interconnect), which is also electrically conductively connected to the voltage clamper component 960 through the contact plug 974 (e.g., a tungsten plug). In certain examples, the voltage clamper component 960 is electrically conductively connected to the drain terminal 916. For example, the voltage clamper component 960 is also electrically conductively connected to the contact 962 through the contact plug 970 (e.g., a tungsten plug). As an example, the contact 962 is electrically conductively connected to the interconnect 964 (e.g., a copper interconnect) through the contact plug 972 (e.g., a tungsten plug), and the interconnect 964 (e.g., a copper interconnect) is electrically conductively connected to the drain terminal 916 through the contact plug 976 (e.g., a tungsten plug).

In certain embodiments, the voltage clamper component 960 can help limit the voltage drop (e.g., V_{ds_Si}) from the drain terminal 916 to the source terminal 914 of the enhancement-mode silicon transistor 910, so that the voltage drop (e.g., Vas Si) from the drain terminal 916 to the source terminal 914 of the enhancement-mode silicon transistor 910 does not exceed a predetermined maximum value. In some examples, the voltage clamper component 960 can help prevent damage to the gate terminal 662 of the depletion-mode gallium nitride transistor 660 of the power device 600 if the power device 600 includes the enhancement-mode silicon transistor 910 as the enhancement-mode silicon transistor 610.

In some embodiments, the enhancement-mode silicon transistor 910 is used as the enhancement-mode silicon transistor 610 of the power device 600. For example, the gate terminal 912 of the enhancement-mode silicon transistor 910 is used as the gate terminal 612 of the enhancement-mode silicon transistor 610. As an example, the source terminal 914 of the enhancement-mode silicon transistor 910 is used as the source terminal 614 of the enhancement-mode silicon transistor 610. For example, the drain terminal 916 of the enhancement-mode silicon transistor 910 is used as the drain terminal 616 of the enhancement-mode silicon transistor 610.

As mentioned above and further emphasized here, FIG. 7, FIG. 8, and FIG. 9 are merely examples, which should not unduly limit the scope of the claims. One of ordinary skill in the art would recognize many variations, alternatives, and modifications. For example, the enhancement-mode silicon transistor as part of the power device 600 includes both the electrostatic discharge protection (ESD) component 760 and the resistor component 860. As an example, the enhancement-mode silicon transistor as part of the power device 600 includes both the electrostatic discharge protection (ESD) component 760 as shown in FIG. 7 and the voltage clamper component 960 as shown in FIG. 9. For example, the enhancement-mode silicon transistor as part of the power device 600 includes both the resistor component 860 as shown in FIG. 8 and the voltage clamper component 960 as shown in FIG. 9. As an example, the enhancement-mode silicon transistor as part of the power device 600 includes all of the electrostatic discharge protection (ESD) component 760 as shown in FIG. 7, the resistor component 860 as shown in FIG. 8, and the voltage clamper component 960 as shown in FIG. 9.

FIG. 10 is a simplified diagram showing an enhancement-mode silicon transistor as part of the power device 600 as shown in FIG. 6 according to certain embodiments of the present disclosure. This diagram is merely an example, which should not unduly limit the scope of the claims. One of ordinary skill in the art would recognize many variations, alternatives, and modifications. The enhancement-mode silicon transistor 1010 includes a gate terminal 1012, a source terminal 1014, and a drain terminal 1016. Additionally, the enhancement-mode silicon transistor 1010 includes the electrostatic discharge protection (ESD) component 1070, the resistor component 1080, and the voltage clamper component 1090. For example, the enhancement-mode silicon transistor 1010 has a threshold voltage that ranges from 3 volts to 5 volts. As an example, the enhancement-mode silicon transistor 1010 is a low-voltage enhancement-mode silicon transistor. Although the above has been shown using a selected group of components for the enhancement-mode silicon transistor, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In some embodiments, the electrostatic discharge protection (ESD) component 1070 is the electrostatic discharge protection (ESD) component 760 as shown in FIG. 7, the resistor component 1080 is the resistor component 860 as shown in FIG. 8, and the voltage clamper component 1090 is the voltage clamper component 960 as shown in FIG. 9. For example, the electrostatic discharge protection (ESD) component 1070 is electrically conductively connected to the source terminal 1014 and the gate terminal 1012.

In certain embodiments, the enhancement-mode silicon transistor 1010 includes components of the enhancement-mode silicon transistor 510, the electrostatic discharge protection (ESD) component 760, the resistor component 860, and the voltage clamper component 960. For example, as part of the enhancement-mode silicon transistor 1010, the electrostatic discharge protection (ESD) component 760 is connected to the components of the enhancement-mode silicon transistor 510 as shown in FIG. 7. As an example, as part of the enhancement-mode silicon transistor 1010, the resistor component 860 is connected to the components of the enhancement-mode silicon transistor 510 as shown in FIG. 8. For example, as part of the enhancement-mode silicon transistor 1010, the voltage clamper component 960 is connected to the components of the enhancement-mode silicon transistor 510 as shown in FIG. 9.

According to some embodiments, the enhancement-mode silicon transistor 1010 is used as the enhancement-mode silicon transistor 610 of the power device 600. For example, the gate terminal 1012 of the enhancement-mode silicon transistor 1010 is used as the gate terminal 612 of the enhancement-mode silicon transistor 610. As an example, the source terminal 1014 of the enhancement-mode silicon transistor 1010 is used as the source terminal 614 of the enhancement-mode silicon transistor 610. For example, the drain terminal 1016 of the enhancement-mode silicon transistor 1010 is used as the drain terminal 616 of the enhancement-mode silicon transistor 610.

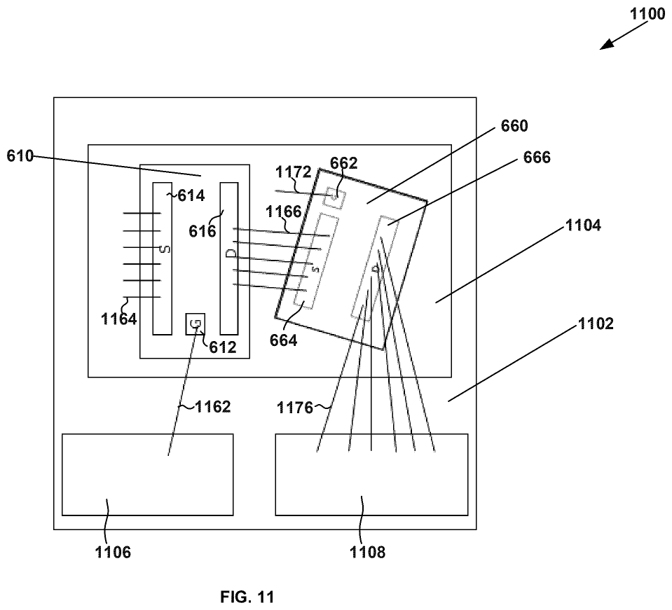

FIG. 11 is a simplified diagram showing certain components of a chip package for the power device 600 as shown in FIG. 6 according to some embodiments of the present disclosure. This diagram is merely an example, which should not unduly limit the scope of the claims. One of ordinary skill in the art would recognize many variations, alternatives, and modifications. The chip package 1100 includes a lead frame 1102 and electrically conductive plates 1104, 1106 and 1108. Additionally, the chip package 1100 includes the enhancement-mode silicon transistor 610 and the depletion-mode gallium nitride transistor 660. Although the above has been shown using a selected group of components for the power device, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In certain embodiments, the depletion-mode gallium nitride transistor 660 is placed on the electrically conductive plate 1104 by attaching the surface 320 of the depletion-mode gallium nitride transistor 660 to the electrically conductive plate 1104. For example, the surface 320 of the depletion-mode gallium nitride transistor 660 is attached to the electrically conductive plate 1104 through electrically conductive paste (e.g., silver conductive paste). As an example, the surface 320 of the depletion-mode gallium nitride transistor 660 is electrically conductively connected to the electrically conductive plate 1104.

In some embodiments, the enhancement-mode silicon transistor 610 is placed on the electrically conductive plate 1104 by attaching the surface 544, the surface 744, the surface 844, and/or the surface 944 of the enhancement-mode silicon transistor 610 to the electrically conductive plate 1104. For example, the surface 544, the surface 744, the surface 844, and/or the surface 944 of the enhancement-mode silicon transistor 610 is attached to the electrically conductive plate 1104 through electrically conductive paste (e.g., silver conductive paste). As an example, the surface 544, the surface 744, the surface 844, and/or the surface 944 of the enhancement-mode silicon transistor 610 is electrically conductively connected to the electrically conductive plate 1104.

According to certain embodiments, the enhancement-mode silicon transistor 610 is the low-voltage enhancement-mode silicon transistor 510, and the depletion-mode gallium nitride transistor 660 is the depletion-mode gallium nitride transistor 360. For example, the surface 544 of the enhancement-mode silicon transistor 610 (e.g., the low-voltage enhancement-mode silicon transistor 510) is electrically conductively connected to the electrically conductive plate 1104, and the surface 320 of the depletion-mode gallium nitride transistor 660 (e.g., the depletion-mode gallium nitride transistor 360) is electrically conductively connected to the electrically conductive plate 1104. As an example, the surface 544 of the enhancement-mode silicon transistor 610 (e.g., the low-voltage enhancement-mode silicon transistor 510) is electrically conductively connected to the surface 320 of the depletion-mode gallium nitride transistor 660 (e.g., the depletion-mode gallium nitride transistor 360) through the electrically conductive plate 1104.

According to some embodiments, the enhancement-mode silicon transistor 610 is the enhancement-mode silicon transistor 710, and the depletion-mode gallium nitride transistor 660 is the depletion-mode gallium nitride transistor 360. For example, the surface 744 of the enhancement-mode silicon transistor 610 (e.g., the enhancement-mode silicon transistor 710) is electrically conductively connected to the electrically conductive plate 1104, and the surface 320 of the depletion-mode gallium nitride transistor 660 (e.g., the depletion-mode gallium nitride transistor 360) is electrically conductively connected to the electrically conductive plate 1104. As an example, the surface 744 of the enhancement-mode silicon transistor 610 (e.g., the enhancement-mode silicon transistor 710) is electrically conductively connected to the surface 320 of the depletion-mode gallium nitride transistor 660 (e.g., the depletion-mode gallium nitride transistor 360) through the electrically conductive plate 1104.

According to certain embodiments, the enhancement-mode silicon transistor 610 is the enhancement-mode silicon transistor 810, and the depletion-mode gallium nitride transistor 660 is the depletion-mode gallium nitride transistor 360. For example, the surface 844 of the enhancement-mode silicon transistor 610 (e.g., the enhancement-mode silicon transistor 810) is electrically conductively connected to the electrically conductive plate 1104, and the surface 320 of the depletion-mode gallium nitride transistor 660 (e.g., the depletion-mode gallium nitride transistor 360) is electrically conductively connected to the electrically conductive plate 1104. As an example, the surface 844 of the enhancement-mode silicon transistor 610 (e.g., the enhancement-mode silicon transistor 810) is electrically conductively connected to the surface 320 of the depletion-mode gallium nitride transistor 660 (e.g., the depletion-mode gallium nitride transistor 360) through the electrically conductive plate 1104.

According to some embodiments, the enhancement-mode silicon transistor 610 is the enhancement-mode silicon transistor 910, and the depletion-mode gallium nitride transistor 660 is the depletion-mode gallium nitride transistor 360. For example, the surface 944 of the enhancement-mode silicon transistor 610 (e.g., the enhancement-mode silicon transistor 910) is electrically conductively connected to the electrically conductive plate 1104, and the surface 320 of the depletion-mode gallium nitride transistor 660 (e.g., the depletion-mode gallium nitride transistor 360) is electrically conductively connected to the electrically conductive plate 1104. As an example, the surface 944 of the enhancement-mode silicon transistor 610 (e.g., the enhancement-mode silicon transistor 910) is electrically conductively connected to the surface 320 of the depletion-mode gallium nitride transistor 660 (e.g., the depletion-mode gallium nitride transistor 360) through the electrically conductive plate 1104.

According to certain embodiments, the enhancement-mode silicon transistor 610 is the enhancement-mode silicon transistor 1010, and the depletion-mode gallium nitride transistor 660 is the depletion-mode gallium nitride transistor 360. For example, a silicon surface (e.g., the surface 544, the surface 744, the surface 844, and/or the surface 944) of the enhancement-mode silicon transistor 610 (e.g., the enhancement-mode silicon transistor 1010) is electrically conductively connected to the electrically conductive plate 1104, and the surface 320 of the depletion-mode gallium nitride transistor 660 (e.g., the depletion-mode gallium nitride transistor 360) is electrically conductively connected to the electrically conductive plate 1104. As an example, the silicon surface (e.g., the surface 544, the surface 744, the surface 844, and/or the surface 944) of the enhancement-mode silicon transistor 610 (e.g., the enhancement-mode silicon transistor 1010) is electrically conductively connected to the surface 320 of the depletion-mode gallium nitride transistor 660 (e.g., the depletion-mode gallium nitride transistor 360) through the electrically conductive plate 1104.

In some embodiments, the enhancement-mode silicon transistor 610 includes the gate terminal 612, the source terminal 614, and the drain terminal 616, and the depletion-mode gallium nitride transistor 660 includes the gate terminal 662, the source terminal 664, and the drain terminal 666. In some examples, the gate terminal 612 of the enhancement-mode silicon transistor 610 is electrically conductively connected to the electrically conductive plate 1106 by one or more electrically conductive wires 1162, and the source terminal 614 of the enhancement-mode silicon transistor 610 is electrically conductively connected to the electrically conductive plate 1104 by one or more electrically conductive wires 1164. For example, the drain terminal 616 of the enhancement-mode silicon transistor 610 is electrically conductively connected to the source terminal 664 of the depletion-mode gallium nitride transistor 660 by one or more electrically conductively wires 1166. In certain examples, the source terminal 664 of the depletion-mode gallium nitride transistor 660 is electrically conductively connected to the drain terminal 616 of the enhancement-mode silicon transistor 610 by one or more electrically conductively wires 1166. As an example, the gate terminal 662 of the depletion-mode gallium nitride transistor 660 is electrically conductively connected to the electrically conductive plate 1104 by one or more electrically conductive wires 1172, and the drain terminal 666 of the depletion-mode gallium nitride transistor 660 is electrically conductively connected to the electrically conductive plate 1108 by one or more electrically conductive wires 1176.

In certain embodiments, as shown in FIG. 11, the drain terminal 616 of the enhancement-mode silicon transistor 610 and the source terminal 664 of the depletion-mode gallium nitride transistor 660 are electrically conductively connected. For example, the electrically conductive plate 1106 is used as the gate terminal 602 of the power device 600, and the electrically conductive plate 1108 is used as the drain terminal 606 of the power device 600. As an example, the source terminal 614 of the enhancement-mode silicon transistor 610 and the gate terminal 662 of the depletion-mode gallium nitride transistor 660 are electrically conductively connected through the electrically conductive plate 1104, which is used as the source terminal 604 of the power device 600.

According to some embodiments, the enhancement-mode silicon transistor 610 has a threshold voltage that ranges from 3 volts to 5 volts. For example, the threshold voltage of the enhancement-mode silicon transistor 610 in the range from 3 volts to 5 volts can help reduce adverse effects of interference on the transistor 610 and/or help improve stability of the power device 600 that includes the transistor 610. As an example, the relatively high threshold voltage of the enhancement-mode silicon transistor 610, which ranges from 3 volts to 5 volts, can help prevent the power device 600 from being turned on mistakenly.

Certain embodiments of the present disclosure provide a chip package of a power device that can improve heat dissipation of the power device, lower packaging costs of the power device, simplify packaging process, and/or reduce the size of the chip package.

According to certain embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; and a first transistor drain terminal electrically conductively connected to a second part of the silicon substrate through the first substrate surface; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor; wherein: the second substrate surface of the silicon substrate and the second structure surface of the transistor structure are electrically conductively connected. For example, the power device is implemented according to at least FIG. 6.

As an example, the power device further includes: a device gate terminal; a device source terminal; and a device drain terminal; wherein: the first transistor gate terminal of the enhancement-mode silicon transistor is the device gate terminal; the first transistor source terminal of the enhancement-mode silicon transistor is the device source terminal; and the second transistor drain terminal of the depletion-mode gallium nitride transistor is the device drain terminal. For example, the first transistor gate terminal is electrically conductively connected to the transistor gate through a first contact plug; the first transistor source terminal is electrically conductively connected to the first part of the silicon substrate through a second contact plug and the first substrate surface; and the first transistor drain terminal is electrically conductively connected to the second part of the silicon substrate through a third contact plug and the first substrate surface. As an example, the first part of the silicon substrate includes a transistor source in the silicon substrate; and the second part of the silicon substrate includes a transistor drain in the silicon substrate. For example, the enhancement-mode silicon transistor is associated with a threshold voltage ranging from 3 volts to 5 volts.

According to some embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; and an electrostatic discharge protection component electrically conductively connected to the first transistor source terminal and electrically conductively connected to the first transistor gate terminal; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor. For example, the power device is implemented according to at least FIG. 6 and/or FIG. 7.

As an example, the electrostatic discharge protection component is electrically conductively connected to the first transistor source terminal through a first contact plug and a second contact plug; and the first transistor source terminal is electrically conductively connected to the first part of the silicon substrate through a third contact plug and the first substrate surface. For example, the electrostatic discharge protection component is electrically conductively connected to the first transistor gate terminal through an interconnect; and the first transistor gate terminal is electrically conductively connected to the transistor gate through a fourth contact plug. As an example, the first part of the silicon substrate includes a transistor source in the silicon substrate; and the second part of the silicon substrate includes a transistor drain in the silicon substrate.

According to certain embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; and a resistor component electrically conductively connected to the first transistor source terminal and electrically conductively connected to a resistor contact; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor. For example, the power device is implemented according to at least FIG. 6 and/or FIG. 8.

As an example, the resistor component is electrically conductively connected to the first transistor source terminal through a first contact plug; and the resistor component is electrically conductively connected to a resistor contact through a second contact plug. For example, the resistor contact is electrically conductively connected to the first transistor gate terminal of the enhancement-mode silicon transistor. As an example, the first part of the silicon substrate includes a transistor source in the silicon substrate; and the second part of the silicon substrate includes a transistor drain in the silicon substrate.

According to some embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; and a voltage clamper component electrically conductively connected to the first transistor source terminal and electrically conductively connected to the first transistor drain terminal; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor. For example, the power device is implemented according to at least FIG. 6 and/or FIG. 9.

As an example, the voltage clamper component is electrically conductively connected to the first transistor source terminal through a first contact plug; and the first transistor source terminal is electrically conductively connected to the first part of the silicon substrate through a second contact plug and the first substrate surface. For example, the voltage clamper component is electrically conductively connected to the first transistor drain terminal through an interconnect; and the first transistor drain terminal is electrically conductively connected to the second part of the silicon substrate through a third contact plug and the first substrate surface. As an example, the first part of the silicon substrate includes a transistor source in the silicon substrate; and the second part of the silicon substrate includes a transistor drain in the silicon substrate.

According to certain embodiments, a power device including a silicon transistor and a gallium nitride transistor, the power device comprising: an enhancement-mode silicon transistor; and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; a first transistor drain terminal electrically conductively connected to a second part of the silicon substrate through the first substrate surface; an electrostatic discharge protection component electrically conductively connected to the first transistor source terminal and electrically conductively connected to the first transistor gate terminal; a resistor component electrically conductively connected to the first transistor source terminal and electrically conductively connected to a resistor contact; and a voltage clamper component electrically conductively connected to the first transistor source terminal and electrically conductively connected to the first transistor drain terminal; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the first transistor source terminal of the enhancement-mode silicon transistor is electrically conductively connected to the second transistor gate terminal of the depletion-mode gallium nitride transistor; and the first transistor drain terminal of the enhancement-mode silicon transistor is electrically conductively connected to the second transistor source terminal of the depletion-mode gallium nitride transistor. For example, the power device is implemented according to at least FIG. 6 and/or FIG. 10.

As an example, the enhancement-mode silicon transistor is associated with a threshold voltage ranging from 3 volts to 5 volts. For example, the resistor contact is electrically conductively connected to the first transistor gate terminal of the enhancement-mode silicon transistor.

According to some embodiments, a chip package for a power device, the chip package comprising: a first electrically conductive plate; a second electrically conductive plate; a third electrically conductive plate; and a power device including an enhancement-mode silicon transistor and a depletion-mode gallium nitride transistor coupled to the enhancement-mode silicon transistor; wherein the enhancement-mode silicon transistor includes: a silicon substrate including a first substrate surface and a second substrate surface; a first transistor gate terminal electrically conductively connected to a transistor gate, the transistor gate being located on the first substrate surface of the silicon substrate through a dielectric layer; a first transistor source terminal electrically conductively connected to a first part of the silicon substrate through the first substrate surface; and a first transistor drain terminal electrically conductively connected to a second part of the silicon substrate through the first substrate surface; wherein the depletion-mode gallium nitride transistor includes: a transistor structure including a first structure surface and a second structure surface, the transistor structure further including a gallium nitride layer; a second transistor gate terminal on the first structure surface of the transistor structure through a barrier layer; a second transistor source terminal electrically conductively connected to a third part of the gallium nitride layer of the transistor structure through the first structure surface; and a second transistor drain terminal electrically conductively connected to a fourth part of the gallium nitride layer of the transistor structure through the first structure surface; wherein: the second substrate surface of the silicon substrate is electrically conductively attached to the first electrically conductive plate; and the second structure surface of the transistor structure is electrically conductively attached to the first electrically conductive plate; wherein: the first transistor gate terminal of the enhancement-mode silicon transistor is electrically conductively connected to the second electrically conductive plate; the first transistor source terminal of the enhancement-mode silicon transistor is electrically conductively connected to the first electrically conductive plate; and the first transistor drain terminal of the enhancement-mode silicon transistor is electrically conductively connected to the second transistor source terminal of the depletion-mode gallium nitride transistor; wherein: the second transistor gate terminal of the depletion-mode gallium nitride transistor is electrically conductively connected to the first electrically conductive plate; and the second transistor drain terminal of the depletion-mode gallium nitride transistor is electrically conductively connected to the third electrically conductive plate. For example, the chip package is implemented according to at least FIG. 11.

As an example, the chip package further includes: a device gate terminal; a device drain terminal; and a device source terminal; wherein: the second electrically conductive plate is the device gate terminal; the third electrically conductive plate is the device drain terminal; and the first electrically conductive plate is the device source terminal. For example, the second substrate surface of the silicon substrate is electrically conductively attached to the first electrically conductive plate through a first electrically conductive paste; and the second structure surface of the transistor structure is electrically conductively attached to the first electrically conductive plate through a second electrically conductive paste; wherein: the second substrate surface of the silicon substrate and the second structure surface of the transistor structure are electrically conductively connected. As an example, the first transistor gate terminal of the enhancement-mode silicon transistor is electrically conductively connected to the second electrically conductive plate by one or more first electrically conductive wires; the first transistor source terminal of the enhancement-mode silicon transistor is electrically conductively connected to the first electrically conductive plate by one or more second electrically conductive wires; and the first transistor drain terminal of the enhancement-mode silicon transistor is electrically conductively connected to the second transistor source terminal of the depletion-mode gallium nitride transistor by one or more third electrically conductive wires. For example, the second transistor gate terminal of the depletion-mode gallium nitride transistor is electrically conductively connected to the first electrically conductive plate by one or more fourth electrically conductive wires; and the second transistor drain terminal of the depletion-mode gallium nitride transistor is electrically conductively connected to the third electrically conductive plate by one or more fifth electrically conductive wires.

For example, some or all components of various embodiments of the present disclosure each are, individually and/or in combination with at least another component, implemented using one or more software components, one or more hardware components, and/or one or more combinations of software and hardware components. As an example, some or all components of various embodiments of the present disclosure each are, individually and/or in combination with at least another component, implemented in one or more circuits, such as one or more analog circuits and/or one or more digital circuits. For example, various embodiments and/or examples of the present disclosure can be combined.

Although specific embodiments of the present disclosure have been described, it will be understood by those of skill in the art that there are other embodiments that are equivalent to the described embodiments. Accordingly, it is to be understood that the invention is not to be limited by the specific illustrated embodiments.

What is claimed is:

1. A power device including a silicon transistor and a gallium nitride transistor, the power device comprising:
an enhancement-mode silicon transistor; and
a depletion-mode gallium nitride transistor coupled to the enhancement-mode silicon transistor;
wherein the enhancement-mode silicon transistor includes:
a silicon substrate including a first substrate surface and a second substrate surface;
a first transistor gate terminal electrically conductively connected to a transistor gate, the transistor gate being located on the first substrate surface of the silicon substrate through a dielectric layer;
a first transistor source terminal electrically conductively connected to a first part of the silicon substrate through the first substrate surface; and
a first transistor drain terminal electrically conductively connected to a second part of the silicon substrate through the first substrate surface;
wherein the depletion-mode gallium nitride transistor includes:
a transistor structure including a first structure surface and a second structure surface, the transistor structure further including a gallium nitride layer;
a second transistor gate terminal on the first structure surface of the transistor structure through a barrier layer;
a second transistor source terminal electrically conductively connected to a third part of the gallium nitride layer of the transistor structure through the first structure surface; and
a second transistor drain terminal electrically conductively connected to a fourth part of the gallium nitride layer of the transistor structure through the first structure surface;
wherein:
the first transistor source terminal of the enhancement-mode silicon transistor is electrically conductively connected to the second transistor gate terminal of the depletion-mode gallium nitride transistor; and
the first transistor drain terminal of the enhancement-mode silicon transistor is electrically conductively connected to the second transistor source terminal of the depletion-mode gallium nitride transistor;
wherein:
the second substrate surface of the silicon substrate and the second structure surface of the transistor structure are electrically conductively connected.

2. The power device of claim 1, and further comprising:
a device gate terminal;
a device source terminal; and
a device drain terminal;
wherein:
the first transistor gate terminal of the enhancement-mode silicon transistor is the device gate terminal;
the first transistor source terminal of the enhancement-mode silicon transistor is the device source terminal; and
the second transistor drain terminal of the depletion-mode gallium nitride transistor is the device drain terminal.

3. The power device of claim 1 wherein:
the first transistor gate terminal is electrically conductively connected to the transistor gate through a first contact plug;
the first transistor source terminal is electrically conductively connected to the first part of the silicon substrate through a second contact plug and the first substrate surface; and
the first transistor drain terminal is electrically conductively connected to the second part of the silicon substrate through a third contact plug and the first substrate surface.

4. The power device of claim 3 wherein:
the first part of the silicon substrate includes a transistor source in the silicon substrate; and
the second part of the silicon substrate includes a transistor drain in the silicon substrate.

5. The power device of claim 1 wherein the enhancement-mode silicon transistor is associated with a threshold voltage ranging from 3 volts to 5 volts.

6. A power device including a silicon transistor and a gallium nitride transistor, the power device comprising:
an enhancement-mode silicon transistor; and
a depletion-mode gallium nitride transistor coupled to the enhancement-mode silicon transistor;
wherein the enhancement-mode silicon transistor includes:
a silicon substrate including a first substrate surface and a second substrate surface;
a first transistor gate terminal electrically conductively connected to a transistor gate, the transistor gate being located on the first substrate surface of the silicon substrate through a dielectric layer;
a first transistor source terminal electrically conductively connected to a first part of the silicon substrate through the first substrate surface;
a first transistor drain terminal electrically conductively connected to a second part of the silicon substrate through the first substrate surface; and
an electrostatic discharge protection component electrically conductively connected to the first transistor source terminal and electrically conductively connected to the first transistor gate terminal;
wherein the depletion-mode gallium nitride transistor includes:
a transistor structure including a first structure surface and a second structure surface, the transistor structure further including a gallium nitride layer;
a second transistor gate terminal on the first structure surface of the transistor structure through a barrier layer;
a second transistor source terminal electrically conductively connected to a third part of the gallium nitride layer of the transistor structure through the first structure surface; and
a second transistor drain terminal electrically conductively connected to a fourth part of the gallium nitride layer of the transistor structure through the first structure surface;
wherein:
the first transistor source terminal of the enhancement-mode silicon transistor is electrically conductively connected to the second transistor gate terminal of the depletion-mode gallium nitride transistor; and
the first transistor drain terminal of the enhancement-mode silicon transistor is electrically conductively connected to the second transistor source terminal of the depletion-mode gallium nitride transistor.

7. The power device of claim 6 wherein:
the electrostatic discharge protection component is electrically conductively connected to the first transistor source terminal through a first contact plug and a second contact plug; and
the first transistor source terminal is electrically conductively connected to the first part of the silicon substrate through a third contact plug and the first substrate surface.

8. The power device of claim 7 wherein:
the electrostatic discharge protection component is electrically conductively connected to the first transistor gate terminal through an interconnect; and
the first transistor gate terminal is electrically conductively connected to the transistor gate through a fourth contact plug.

9. The power device of claim 8 wherein:
the first part of the silicon substrate includes a transistor source in the silicon substrate; and
the second part of the silicon substrate includes a transistor drain in the silicon substrate.

10. A power device including a silicon transistor and a gallium nitride transistor, the power device comprising:
an enhancement-mode silicon transistor; and
a depletion-mode gallium nitride transistor coupled to the enhancement-mode silicon transistor;
wherein the enhancement-mode silicon transistor includes:
a silicon substrate including a first substrate surface and a second substrate surface;
a first transistor gate terminal electrically conductively connected to a transistor gate, the transistor gate being located on the first substrate surface of the silicon substrate through a dielectric layer;
a first transistor source terminal electrically conductively connected to a first part of the silicon substrate through the first substrate surface;
a first transistor drain terminal electrically conductively connected to a second part of the silicon substrate through the first substrate surface; and
a resistor component electrically conductively connected to the first transistor source terminal and electrically conductively connected to a resistor contact;
wherein the depletion-mode gallium nitride transistor includes:
a transistor structure including a first structure surface and a second structure surface, the transistor structure further including a gallium nitride layer;
a second transistor gate terminal on the first structure surface of the transistor structure through a barrier layer;
a second transistor source terminal electrically conductively connected to a third part of the gallium nitride layer of the transistor structure through the first structure surface; and
a second transistor drain terminal electrically conductively connected to a fourth part of the gallium nitride layer of the transistor structure through the first structure surface;
wherein:
the first transistor source terminal of the enhancement-mode silicon transistor is electrically conductively connected to the second transistor gate terminal of the depletion-mode gallium nitride transistor; and
the first transistor drain terminal of the enhancement-mode silicon transistor is electrically conductively connected to the second transistor source terminal of the depletion-mode gallium nitride transistor.

11. The power device of claim 10 wherein:
the resistor component is electrically conductively connected to the first transistor source terminal through a first contact plug; and
the resistor component is electrically conductively connected to a resistor contact through a second contact plug.

12. The power device of claim 11 wherein the resistor contact is electrically conductively connected to the first transistor gate terminal of the enhancement-mode silicon transistor.

13. The power device of claim 12 wherein:
the first part of the silicon substrate includes a transistor source in the silicon substrate; and
the second part of the silicon substrate includes a transistor drain in the silicon substrate.

14. A power device including a silicon transistor and a gallium nitride transistor, the power device comprising:
an enhancement-mode silicon transistor; and
a depletion-mode gallium nitride transistor coupled to the enhancement-mode silicon transistor;
wherein the enhancement-mode silicon transistor includes:
a silicon substrate including a first substrate surface and a second substrate surface;
a first transistor gate terminal electrically conductively connected to a transistor gate, the transistor gate being located on the first substrate surface of the silicon substrate through a dielectric layer;
a first transistor source terminal electrically conductively connected to a first part of the silicon substrate through the first substrate surface;
a first transistor drain terminal electrically conductively connected to a second part of the silicon substrate through the first substrate surface; and
a voltage clamper component electrically conductively connected to the first transistor source terminal and electrically conductively connected to the first transistor drain terminal;
wherein the depletion-mode gallium nitride transistor includes:
a transistor structure including a first structure surface and a second structure surface, the transistor structure further including a gallium nitride layer;
a second transistor gate terminal on the first structure surface of the transistor structure through a barrier layer;
a second transistor source terminal electrically conductively connected to a third part of the gallium nitride layer of the transistor structure through the first structure surface; and
a second transistor drain terminal electrically conductively connected to a fourth part of the gallium nitride layer of the transistor structure through the first structure surface;
wherein:
the first transistor source terminal of the enhancement-mode silicon transistor is electrically conductively connected to the second transistor gate terminal of the depletion-mode gallium nitride transistor; and
the first transistor drain terminal of the enhancement-mode silicon transistor is electrically conductively connected to the second transistor source terminal of the depletion-mode gallium nitride transistor.

15. The power device of claim 14 wherein:
the voltage clamper component is electrically conductively connected to the first transistor source terminal through a first contact plug; and
the first transistor source terminal is electrically conductively connected to the first part of the silicon substrate through a second contact plug and the first substrate surface.

16. The power device of claim 15 wherein:
the voltage clamper component is electrically conductively connected to the first transistor drain terminal through an interconnect; and
the first transistor drain terminal is electrically conductively connected to the second part of the silicon substrate through a third contact plug and the first substrate surface.

17. The power device of claim 16 wherein:
the first part of the silicon substrate includes a transistor source in the silicon substrate; and
the second part of the silicon substrate includes a transistor drain in the silicon substrate.

18. A power device including a silicon transistor and a gallium nitride transistor, the power device comprising:
an enhancement-mode silicon transistor; and
a depletion-mode gallium nitride transistor coupled to the enhancement-mode silicon transistor;
wherein the enhancement-mode silicon transistor includes:
a silicon substrate including a first substrate surface and a second substrate surface;
a first transistor gate terminal electrically conductively connected to a transistor gate, the transistor gate being located on the first substrate surface of the silicon substrate through a dielectric layer;
a first transistor source terminal electrically conductively connected to a first part of the silicon substrate through the first substrate surface;
a first transistor drain terminal electrically conductively connected to a second part of the silicon substrate through the first substrate surface;
an electrostatic discharge protection component electrically conductively connected to the first transistor source terminal and electrically conductively connected to the first transistor gate terminal;
a resistor component electrically conductively connected to the first transistor source terminal and electrically conductively connected to a resistor contact; and
a voltage clamper component electrically conductively connected to the first transistor source terminal and electrically conductively connected to the first transistor drain terminal;
wherein the depletion-mode gallium nitride transistor includes:
a transistor structure including a first structure surface and a second structure surface, the transistor structure further including a gallium nitride layer;
a second transistor gate terminal on the first structure surface of the transistor structure through a barrier layer;
a second transistor source terminal electrically conductively connected to a third part of the gallium nitride layer of the transistor structure through the first structure surface; and
a second transistor drain terminal electrically conductively connected to a fourth part of the gallium nitride layer of the transistor structure through the first structure surface;
wherein:
the first transistor source terminal of the enhancement-mode silicon transistor is electrically conductively connected to the second transistor gate terminal of the depletion-mode gallium nitride transistor; and
the first transistor drain terminal of the enhancement-mode silicon transistor is electrically conductively connected to the second transistor source terminal of the depletion-mode gallium nitride transistor.

19. The power device of claim 18 wherein the enhancement-mode silicon transistor is associated with a threshold voltage ranging from 3 volts to 5 volts.

20. The power device of claim 18 wherein the resistor contact is electrically conductively connected to the first transistor gate terminal of the enhancement-mode silicon transistor.

21. A chip package for a power device, the chip package comprising:
a first electrically conductive plate;
a second electrically conductive plate;
a third electrically conductive plate; and
a power device including an enhancement-mode silicon transistor and a depletion-mode gallium nitride transistor coupled to the enhancement-mode silicon transistor;
wherein the enhancement-mode silicon transistor includes:
a silicon substrate including a first substrate surface and a second substrate surface;
a first transistor gate terminal electrically conductively connected to a transistor gate, the transistor gate being located on the first substrate surface of the silicon substrate through a dielectric layer;
a first transistor source terminal electrically conductively connected to a first part of the silicon substrate through the first substrate surface; and
a first transistor drain terminal electrically conductively connected to a second part of the silicon substrate through the first substrate surface;
wherein the depletion-mode gallium nitride transistor includes:
a transistor structure including a first structure surface and a second structure surface, the transistor structure further including a gallium nitride layer;
a second transistor gate terminal on the first structure surface of the transistor structure through a barrier layer;
a second transistor source terminal electrically conductively connected to a third part of the gallium nitride layer of the transistor structure through the first structure surface; and
a second transistor drain terminal electrically conductively connected to a fourth part of the gallium nitride layer of the transistor structure through the first structure surface;
wherein:
the second substrate surface of the silicon substrate is electrically conductively attached to the first electrically conductive plate; and
the second structure surface of the transistor structure is electrically conductively attached to the first electrically conductive plate;
wherein:
the first transistor gate terminal of the enhancement-mode silicon transistor is electrically conductively connected to the second electrically conductive plate;
the first transistor source terminal of the enhancement-mode silicon transistor is electrically conductively connected to the first electrically conductive plate; and
the first transistor drain terminal of the enhancement-mode silicon transistor is electrically conductively connected to the second transistor source terminal of the depletion-mode gallium nitride transistor;
wherein:
the second transistor gate terminal of the depletion-mode gallium nitride transistor is electrically conductively connected to the first electrically conductive plate; and
the second transistor drain terminal of the depletion-mode gallium nitride transistor is electrically conductively connected to the third electrically conductive plate.

22. The chip package of claim 21, and further comprising:
a device gate terminal;
a device drain terminal; and
a device source terminal;
wherein:
the second electrically conductive plate is the device gate terminal;
the third electrically conductive plate is the device drain terminal; and
the first electrically conductive plate is the device source terminal.

23. The chip package of claim 21 wherein:
the second substrate surface of the silicon substrate is electrically conductively attached to the first electrically conductive plate through a first electrically conductive paste; and
the second structure surface of the transistor structure is electrically conductively attached to the first electrically conductive plate through a second electrically conductive paste;
wherein:
the second substrate surface of the silicon substrate and the second structure surface of the transistor structure are electrically conductively connected.

24. The chip package of claim 23 wherein:
the first transistor gate terminal of the enhancement-mode silicon transistor is electrically conductively connected to the second electrically conductive plate by one or more first electrically conductive wires;
the first transistor source terminal of the enhancement-mode silicon transistor is electrically conductively connected to the first electrically conductive plate by one or more second electrically conductive wires; and
the first transistor drain terminal of the enhancement-mode silicon transistor is electrically conductively connected to the second transistor source terminal of the depletion-mode gallium nitride transistor by one or more third electrically conductive wires.

25. The chip package of claim 24 wherein:
the second transistor gate terminal of the depletion-mode gallium nitride transistor is electrically conductively connected to the first electrically conductive plate by one or more fourth electrically conductive wires; and
the second transistor drain terminal of the depletion-mode gallium nitride transistor is electrically conductively connected to the third electrically conductive plate by one or more fifth electrically conductive wires.
